(19) United States
(12) Patent Application Publication
(10) Pub. No.: US 2009/0242046 A1
(43) Pub. Date: Oct. 1, 2009

(54) Valve module

(76) Inventor: Benjamin Riordon, Newburyport, MA (US)

Correspondence Address: Nields, Lemack & Frame, LLC, 176 E. MAIN STREET, SUITE 5, WESTBOROUGH, MA, 01581, US

(21) Appl. No.: 12/080,067

(22) Filed: Mar. 31, 2008

(51) Int. Cl. F16K 15/00; F04F 3/00; F24F 7/007

(52) U.S. Cl. 137/512; 137/565.15; 137/565.23; 454/251

(57) ABSTRACT

A system for pressurizing and exhausting a vented chamber is disclosed. The present disclosure includes a unitary module having two integrated valves for each supported chamber, a single inlet port for each chamber, a single vent exhaust port and a single pressurized port. In addition, a number of pressure gauge ports are provided to allow the pressure at various points to be monitored. In addition, the unitary module optionally includes a leak check port. Using this port, the operator can test the integrity of all valves within the module.

### BACKGROUND OF THE INVENTION

In many applications, valves are used to control the flow of fluids within an environment. For example, valves control the flow of gasoline and air in automotive engines or the flow of fluids from tanks. Valves also play an important role in the operation of vacuum and pressure chambers. In these environments, one or more valves are used to selectively provide a path through which fluids (such as gasses) can pass. Often, the valve is opened to allow fluids to be pumped out of the chamber. Once the chamber reaches the desired pressure, the valve is closed, thereby maintaining the chamber at the recommended pressure. This process is also used for pressurized chambers, where, rather than pumping fluid out of the chamber, fluid is pumped into the chamber. Again, once the desired pressure is reached, the valve is closed and the chamber is maintained at the desired pressure.

To monitor the pressure within a chamber, pressure gauges are typically used. These gauges, which can be vacuum gauges in some embodiments, are typically electronic and connect to a control system such that the control system operates the vacuum pumps and valves in response to the current pressure readings. Similarly, in the case of a pressurized chamber, the gauge readings allow the control system to regulate the inflow of pressurized fluid.

Often, in addition to controlling the pressure within a chamber, it is also necessary to properly exhaust the contents of that chamber. Alternatively, it may be necessary to provide a low pressure outlet, such that the chamber is always at negative pressure relative to the external environment when the chamber is opened so that residue does not exit into the environment.

Since compression equipment and vacuum pumps are not inexpensive, often it is advantageous to attempt to share a pump between multiple chambers. FIG. 1 shows a system 100 of the prior art, used to control two vacuum chambers. The system has a first chamber 110 and a second chamber 115. Each optionally has a vacuum gauge 120, 125 affixed directly to it. First chamber 110 has a first conduit 130 that is in communication with a low pressure chamber exhaust 140, via valve 150. When valve 150 is open, chamber 110 is in communication with low pressure chamber exhaust 140. In this way, if chamber 110 is opened by an operator, residual fluids within the chamber, such as gasses, are not emitted into the environment. Rather, since the chamber exhaust 140 is at negative pressure, the opening of the chamber causes air from the environment to flow into the chamber. Second chamber 115 also has a conduit 135 to the chamber exhaust 140 via valve 155. The chambers can operate autonomously with respect to the chamber exhaust 140. In other words, the first chamber 110 may be in fluid communication with chamber exhaust 140; the second chamber 115 may be in fluid communication with chamber exhaust 140; both may be in communication; or neither may be in communication. The use of two valves 150, 155 allows all four of these combinations to occur. In typical applications, conduits 130, 135 are constructed from stainless steel, or another non-corrosive element. In some embodiments, where the fluids within the chamber are toxic, the chamber exhaust 140 may be a remote toxic gas abatement system.

First chamber 110 also has a second conduit 160 that is used to connect the chamber to a pressurized source. In FIG. 1, first and second chambers 110, 115 are vacuum chambers; however, pressurized chambers are also possible. In that scenario, conduits 160, 165 are in communication with a high pressure source. Returning to FIG. 1, conduit 160 includes one or more vacuum gauges 170, 172, and a valve 180. Furthermore, in this embodiment, a rough pump 190, which is preferably a mechanical positive displacement pump, is used to drive the pressure within the chamber to a near vacuum (˜10 mTorr). To bring the chamber even closer to a full vacuum (such as less than 1 mTorr), a high vacuum pump 195 is used in conjunction with the rough pump 190. The high vacuum pump can be either a turbopump or a cryopump. A turbopump is a momentum transfer pump. These devices cannot exhaust directly to atmospheric pressure so the devices pump into a mechanical pump, such as rough pump 190. A cryopump is a capture pump. A cryopump operated similar to a freezer. Gas adsorbs to the arrays. Periodically, the pump needs to be vented (for heat), “regenerated” to an exhaust line, then roughed back to vacuum. The present disclosure applies to both types of high vacuum pumps.

In operation, rough pump 190 is engaged, and valve 180 is opened such that the first chamber 110 is in communication with the rough pump 190. As fluids are pumped out of chamber 110, the pressure within that chamber is lowered. A vacuum gauge 172 measures the pressure at the input to the rough pump. When this pressure is sufficiently low, the high vacuum pump 195 is enabled, while allows the chamber 110 to reach even lower pressures. Once the desired pressure is reached, high vacuum pump 195 can be turned off, and valve 180 can be closed, thereby holding the pressure within the chamber 110. Since the second chamber 115 is connected to the rough pump 190 via a separate conduit 165, valve 185 and vacuum gauge 174, it can operate independently from the first chamber 110. In other words, either chamber, both chambers, or neither chamber may be being evacuated at a given point in time.

Although not shown, typically a pressure fluid source, such as nitrogen gas, is in communication with each chamber so as to pump the chamber back to atmospheric pressure when necessary.

The valves 150, 155, 180, 185 are preferably right angle valves. These valves are designed for high vacuum applications, and include an inlet, and an output that is at a 90° angle to the inlet. The internal structure of the valve includes a column, in line with the inlet. Inside the column, an actuator is used to allow the passage of fluids between the inlet and the outlet. In most embodiments, the actuator includes a solenoid, which is actuated via an electrical connection to the valve. Such valves are readily available and are well known to those of ordinary skill in the art.

The configuration shown in FIG. 1 can be expanded to include an arbitrary number of chambers. All of the recited components are replicated for each additional chamber. However, it is likely that a single chamber exhaust 140 can be used for many chambers. Similarly, a single rough pump 190 can be used for more than two chambers.

While the system described in FIG. 1 is functional, it suffers from many shortcomings. First of all, there are a number of individual valves that are physically separate from one another. Each of these needs to be assembled and leak checked. Second, each pressure gauge requires a dedicated mounting flange and signal harness. Similarly, each valve requires a dedicated mounting flange, hardware, tubing connection and signal harness. In addition, since the valves are physically separate, a number of wiring harnesses must be constructed and connected throughout the system. Finally, this system requires at least one connection to each chamber, one for the chamber exhaust, and one for the vacuum pump.

An improved valve module that performs these functions without the drawbacks of the present implementations would be beneficial.

### SUMMARY OF THE INVENTION

The problems of the prior art are addressed by the present disclosure, which includes a system for pressurizing and exhausting a vented chamber. A unitary module having two integrated valves for each supported chamber, a single inlet port for each chamber, a single vent exhaust port and a single pressurized port is disclosed. In addition, a number of pressure gauge ports are provided to allow the pressure at various points to be monitored.

In addition, the unitary module optionally includes a leak check port. Using this port, the operator can test the integrity of all valves within the module, as well as the module itself.

### BRIEF DESCRIPTION OF THE DRAWINGS

FIG. 1 illustrates a valve system of the prior art;

FIG. 2 illustrates the rear view of the module;

FIG. 3 illustrates a cross-sectional view of the module, taken along lines AA; and

FIG. 4 illustrates a second cross-sectional view of the module taken along lines BB.

### DETAILED DESCRIPTION OF THE INVENTION

As described above, in many applications, chambers need to be pressurized to a given value, and also vented to remove fluids contained within them. The present disclosure describes both of these functions being performed by using a unitary module, which incorporates two valves for each supported chamber.

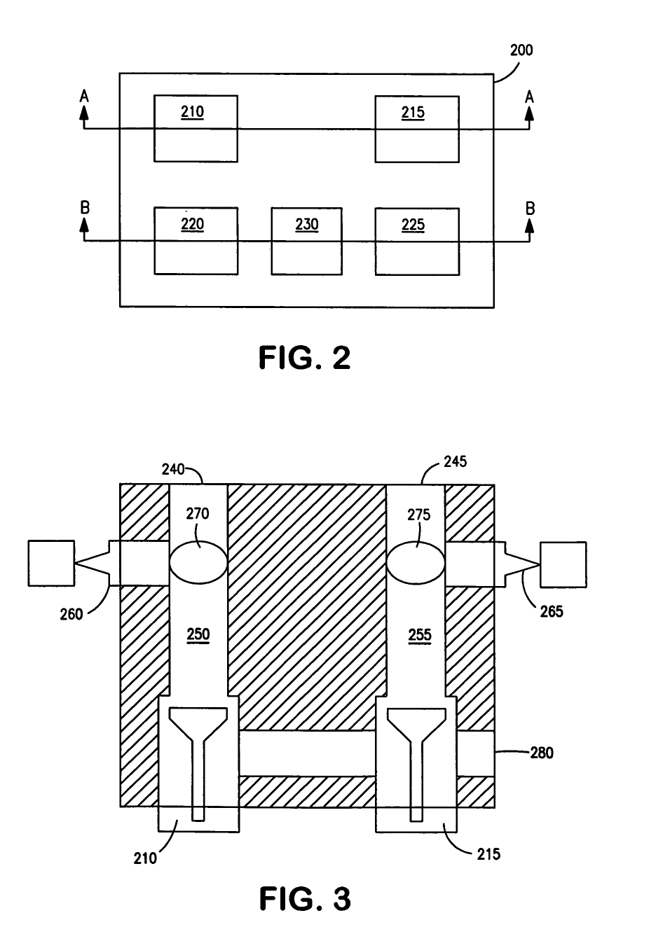

FIG. 2 shows the rear view of the module 200. In this particular embodiment, two chambers are supported by a single module. However, the disclosure is not so limited. By increasing the number of valves, the number of chambers can be increased accordingly. It can be seen in FIG. 2 that the valves are arranged substantially in two rows, and two columns, with an additional leak check port added to the lower row. In the preferred embodiment, two rows are used, regardless of the number of chambers, such that one row contains the valves need for exhausting the chambers, and the second row contains the valves needed for pressurizing the chambers. In the preferred embodiment, the columns each correspond to a particular chamber. For example, FIG. 2 shows two rows and two columns. The upper left valve 210 is the exhaust valve for the first chamber 110. The lower left valve 220 is the pressurizing valve for the first chamber. The upper and lower right valves 215, 225 have corresponding functions for the second chamber 115. Valve 230 represents a leak port valve, which is used to check the integrity of the vacuum system.

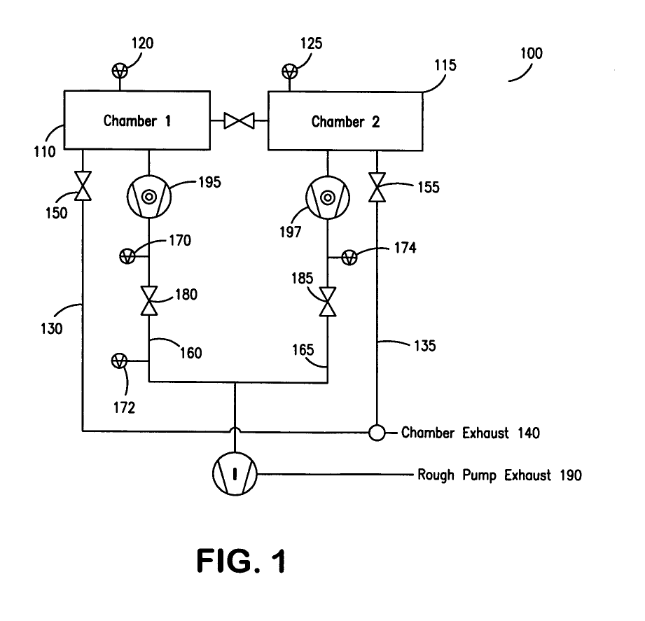

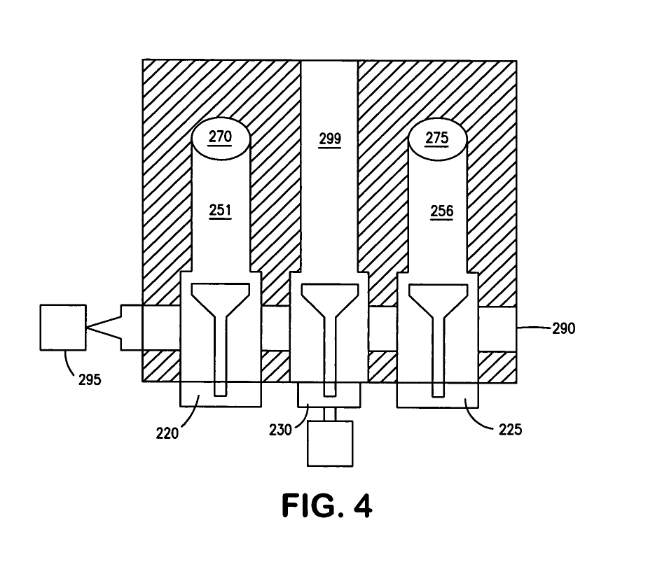

FIG. 2 illustrates two cross-sectional lines AA and BB. FIG. 3 is the cross section of module 220 along line AA, while FIG. 4 is the cross section along line BB. Referring to FIG. 3, valves 210 and 215 can be seen in more detail. Inlet port 240 for the first chamber leads to an inner cavity 250, which may be shaped as a cylinder. In some embodiments, the inlet port 240 is connected directly to the chamber 110. In other embodiments, as is shown in FIG. 1, a high vacuum pump 195 is placed between the chamber 110 and the inlet port 240. This inner cavity 250 has several conduits in communication with it. A pressure gauge port 260 is preferably drilled perpendicular to the major axis of the inner cavity and allows an external pressure gauge to be attached. A blind hole 270 allows fluid communication between the upper row of the module and the lower row. Inner cavity 250 terminates on the upper row at valve 210. When valve 210 is opened, fluid from the inlet 240 passes through inner cavity 250 and is passed out of the module 200 via vent exhaust port 280. When valve 210 is closed, fluid from inner cavity 250 cannot pass through the valve and therefore cannot exit via the vent exhaust port 280. The same set of components is used for the second chamber 115. Fluid enters the module 200 via inlet port 245. Inner cavity 255 is in communication with pressure gauge port 265 and valve 215 on the top row. There is also a blind hole 275 that connects the inner cavity 255 to the lower row. The operation of valve 215 causes the same actions as those described with respect to valve 210 and will not be repeated here. In a preferred embodiment, the inner cavity is shaped as two cylinders, one on each row, which are connected via a blind conduit.

In FIG. 3, the pressure gauge ports 260, 265 are shown to be on the side of the module 200. However, the disclosure is not so limited. These ports can also be on the top side of the module 200. In fact, in the case where more than two chambers are connected to the module 200, the pressure gauge ports must be moved, since the inner inlet ports are not exposed to an outer side. Alternatively, the pressure gauge ports 260, 265 can also be located on the bottom of the module 200. The design of valve 215 is such that fluid entering via conduit 281 can flow out of vent exhaust port 280 regardless of the state of valve 215. Thus, any number of valves can be placed next to one another with a single vent exhaust port 280 located on one side of the module 200.

FIG. 4 shows a second cross section of module 200. Blind hole 270 leads to inner cavity 251. This cylinder terminates in valve 220. When valve 220 is opened, fluid from inner cavity 251 exits the module 200 via pressurized port 290, located on one side of the module. On the opposite side of the module is a pressure gauge port 295, which allows the operator to monitor the pressure at the pressurized port, regardless of the state of the valves 220, 225.

Manual valve 230 is the leak check port. In normal operation, this valve 230 is closed, blocking access to inner cavity 299. When valve 230 is opened, inner cavity 299 is in communication with pressurized port 290 and pressure gauge port 295. To test the integrity of the device, a vacuum pump is attached to the leak check port. A gas analyzer is also in communication with the leak check port. Helium is then introduced at each of the sealing surfaces. If the seal is not tight, the negative pressure caused by the vacuum pump will force helium into the module. This helium would then be detected by the gas analyzer and indicate that the module has been compromised. In the event of a failure, all of the valves would then be opened to check the external integrity of each valve body and all static joints. Each valve would then be individually closed to check the integrity of their seal.

By arranging the valves and pressure gauge ports as described above, it is possible to integrate all of the conduits necessary to implement a venting and pressurizing system for a plurality of chambers.

Having described the preferred configuration of the module 200, its use in a typical application will now be described. In ion implanters, there is a need to maintain various components at vacuum pressure. Two such components are the ion source and the beamline. In this scenario, the ion source is connected to inlet port 240, via a high vacuum pump, while the beamline chamber is connected to inlet port 245 via a separate high vacuum pump. Pressurized port 290 is in communication with a rough pump, while vent exhaust port 280 is in communication with a remote toxic gas abatement system. The ion source and beamline are kept at vacuum pressure through the use of the module 200.

At those times when the vacuum chamber needs to be opened, such as for maintenance, it is essential to insure that gasses that are generated in the chamber do not escape into the outside environment. For purposes of illustration, assume that the ion source chamber must be serviced. In this scenario, the vacuum chamber is pumped to atmospheric pressure with nitrogen, and then exhausted via vent exhaust port 280. This is done by opening valve 210. This exhaust port leads to a remote toxic gas abatement system and maintains a negative pressure in the chamber. Thus, when the chamber is opened, air from the outside environment is forced into the chamber due to the pressure differential. When the chamber is closed, valve 220 is opened to allow air to be pumped out by the rough pump connected to pressurized port 290. When the pressure in the ion source chamber has reached a certain level, as measured by pressure gauge 260, the high vacuum pump is activated to further reduce the pressure within the ion source.

While this disclosure has been described in conjunction with the specific embodiments disclosed above, it is obvious to one of ordinary skill in the art that many variations and modifications are possible. Accordingly, the embodiments presented in this disclosure are intended to be illustrative and not limiting. Various embodiments can be envisioned without departing from the spirit of the disclosure.

What is claimed is:

1. An unitary module comprising:
a. at least two inlet ports, each of said inlet ports adapted to be in communication with a chamber to be pressurized, wherein each inlet port is in communication with a corresponding inner cavity;
b. an exhaust valve associated with each of said inner cavities, each of said exhaust valves having an inlet and an outlet and wherein the inlet of each exhaust valve is in communication with its corresponding inner cavity;
c. a pressuring valve associated with each of said inner cavities, each of said pressurizing valves having an inlet and an outlet and wherein the inlet of each pressurizing valve is in communication with its corresponding inner cavity;
d. a pressurized port, adapted to be in communication with a pressurized device, in communication with the outlets of all of said pressurizing valves; and
e. an exhaust vent port, in communication with the outlets of all of said exhaust valves.

2. The module of claim 1, further comprising a plurality of pressure gauge ports wherein each of said inner cavities is in communication with a respective pressure gauge port.

3. The module of claim 2, wherein the outlets of all of said pressurizing valves are in communication with a pressure gauge port.

4. The module of claim 1, further comprising a leak check port and an associated valve, said valve having an inlet and an outlet, wherein said inlet is in communication with said outlets of said pressurizing ports and said outlet is in communication with said leak check port.

5. A pressurized chamber system, comprising:
a. at least two chambers to be pressurized, and
b. a unitary module comprising:
i. at least two inlet ports, each of said inlet ports adapted to be in communication with a chamber to be pressurized, wherein each inlet port is in communication with a corresponding inner cavity;
ii. an exhaust valve associated with each of said inner cavities, each of said exhaust valves having an inlet and an outlet and wherein the inlet of each exhaust valve is in communication with its corresponding inner cavity;
iii. a pressuring valve associated with each of said inner cavities, each of said pressurizing valves having an inlet and an outlet and wherein the inlet of each pressurizing valve is in communication with its corresponding inner cavity;
iv. a pressurized port, adapted to be in communication with a pressurized device, in communication with the outlets of all of said pressurizing valves; and
v. an exhaust vent port, in communication with the outlets of all of said exhaust valves.

6. The system of claim 5, wherein said chambers comprise vacuum chambers and said pressurized device comprises a vacuum pump.

7. The system of claim 5, further comprising at least two high vacuum pumps, each high vacuum pump having an inlet in communication with an associated chamber and an outlet in communication with a respective inlet port of said module.

8. The system of claim 5, further comprising a toxic gas abatement system in communication with said exhaust vent port.

9. The system of claim 6, wherein said first chamber comprises an ion source vacuum chamber and said second chamber comprises a beamline vacuum chamber.

10. The system of claim 5, further comprising a plurality of pressure gauge ports wherein each of said inner cavities is in communication with a respective pressure gauge port.

11. The module of claim 10, wherein the outlets of all of said pressurizing valves are in communication with a pressure gauge port.

12. The system of claim 11, further comprising a plurality of pressure gauges, each in communication with a respective pressure gauge port.

13. The system of claim 12, wherein said pressure gauges comprise vacuum gauges.
